(19) United States
(12) Patent Application Publication
(10) Pub. No.: US 2025/0091463 A1
(43) Pub. Date: Mar. 20, 2025

(54) METHOD AND DEVICE FOR CHARGING A HIGH VOLTAGE BATTERY

(71) Applicant: Preh GmbH, Bad Neustadt a.d. Saale (DE)

(72) Inventors: Marc NEITZ, Oberelsbach (DE); Alexander MATTHIAS, Kaltennordheim (DE)

(73) Assignee: Preh GmbH, Bad Neustadt a.d. Saale (DE)

(21) Appl. No.: 18/728,306

(22) PCT Filed: Oct. 26, 2022
(86) PCT No.: PCT/EP2022/079920

§ 371 Date: Jul. 11, 2024

(30) Foreign Application Priority Data
Jan. 14, 2022 (DE) 10 2022 100 846.0

(51) Int. Cl. B60L 53/62; B60L 53/30; G01R 31/3835; G01R 31/389; H02J 7/00

(52) U.S. Cl. CPC B60L 53/62; B60L 53/30; G01R 31/3835; G01R 31/389; H02J 7/00308

(57) ABSTRACT

The present disclosure relates to a method for charging a high-voltage battery, having the steps of: providing the high-voltage battery with a nominal battery voltage, providing a charging station with a nominal charging voltage, which is lower than the nominal battery voltage, connecting a station-side protective earth conductor terminal to a battery-side protective earth conductor terminal to form a protective earth conductor, adjusting a voltage between a first, battery-side high-voltage potential and the protective earth conductor to equal half the nominal charging voltage, electrically connecting a first station-side high-voltage potential to the first battery-side high-voltage potential, electrically connecting a second station-side high-voltage potential to a second battery-side high-voltage potential, and controlling the discharge current by means of a resistance control. The present disclosure also relates to a device configured to charge a high-voltage battery.

### TECHNICAL FIELD

The present disclosure relates to a method for charging a high-voltage battery, in particular a high-voltage battery of an electric vehicle, and to a device for charging such a high-voltage battery.

### BACKGROUND

Electric vehicles (EV), such as for example hybrid electric vehicles (HEV) or battery electric vehicles (BEV), usually have a high-voltage battery (for example traction battery) as an energy storage unit having a nominal voltage of for example 400 V or 800 V. A high voltage or high-voltage potential (hereinafter also referred to as HV potential for short) is understood here—as is common in the automotive sector—to mean a DC voltage of greater than 60 V, in particular greater than 200 V, such as for example 400 V or 800 V up to around 1500 V. A low voltage or low-voltage potential is understood to mean a voltage of less than or equal to 60 V, for example 12 V, 24 V, 48 V or 60 V. The terms high voltage and low voltage are used, in connection with the various embodiments disclosed herein, synonymously with the terms high-voltage or low-voltage potential with the voltage levels or voltage ranges specified above.

It is generally known to use insulation monitoring devices or what are known as “ISO monitors” in high-voltage grids to measure an insulation resistance between PE (protective earth) and the high voltage-carrying cables in order to be able to ensure the operational safety of the high-voltage grid. If the insulation resistance ascertained from the measurement is too low, a safety mechanism is able to interrupt the current transmission in the grid, for example by opening a switch, relay or the like.

If an electric vehicle having a high-voltage battery, for example a battery having a nominal voltage of 800 V, is charged at a charging station that provides a lower charging voltage than the battery nominal voltage, that is to say less than 800 V in the given example, for example 400 V, it is also customary to use a DC/DC step-up converter to convert the voltage provided by the charging station such that it corresponds to the nominal voltage of the high-voltage battery of the electric vehicle. Such a DC-DC converter may be provided for example in the electric vehicle.

Depending on the circuit topology, the connection of the high-voltage battery to a higher nominal voltage than the charging voltage provided by the charging station may lead to an asymmetry, that is to say a shift of the electrical potential, between the high-voltage potentials and the protective earth (PE). As a result, the permissible range of an insulation voltage may be exceeded. Moreover, an ISO monitor may calculate an incorrect insulation resistance, in particular in the case of dynamic compensation processes, for example at the start of a charging process. The ISO monitor, which monitors the insulation resistance between protective earth (PE) and the high-voltage side (HV), interprets a high current rise resulting from the asymmetry as an erroneous insulation resistance and interrupts the charging process. Electric vehicles having high-voltage batteries that have a higher battery nominal voltage than a charging voltage provided by a charging station therefore cannot be charged, or at least cannot be charged reliably, at such charging stations.

Against this background, the present disclosure is based on the object of providing a method and a charging device that each enable charging of a high-voltage battery at a charging station that provides a lower charging nominal voltage than the nominal voltage of the high-voltage battery, wherein the charging is intended to be carried out in a safe, stable, reliable and energy-efficient manner. The charging method and the charging device are also intended to be able to be implemented easily and inexpensively in technical terms and to have a compact and lightweight structure.

This object is achieved by a method having the features of claim 1 and a device having the features of claim 11. Further particularly advantageous embodiments of the present disclosure are disclosed in the respective dependent claims.

It should be noted that the features listed individually in the claims may be combined with one another in any technically feasible manner (including beyond category boundaries, for example between method and device) and bring about further embodiments of the present disclosure. The description additionally characterizes and specifies the present disclosure, in particular in connection with the figures.

It should also be noted that an “and/or” conjunction used herein, placed between two features and linking said features to one another, should always be interpreted to mean that only the first feature may be present in a first embodiment of the subject matter according to the present disclosure, only the second feature may be present in a second embodiment, and both the first and the second feature may be present in a third embodiment.

In addition, a term “around” used herein is intended to indicate a tolerance range that is considered to be normal by a person skilled in the art working in the present field. In particular, the term “around” should be understood to mean a tolerance range of the quantity in question of up to at most +/−20%, preferably up to at most +/−10%.

Relative terms in relation to a feature, such as for example “larger”, “smaller”, “higher”, “lower” and the like, should be interpreted in the context of the present disclosure to mean that manufacturing-related and/or performance-related quantity variations of the feature in question that fall within the manufacturing/performance tolerances defined for the respective manufacturing or performance of the feature in question are not covered by the relative term in question. In other words, a quantity in relation to a feature should be considered for example to be “larger”, “smaller”, “higher”, “lower” and the like than a quantity in relation to a comparative feature only when the two quantities under comparison differ from one another in terms of their value to such a clear extent that it is certain that this value difference does not fall within the manufacturing-related/performance-related tolerance range of the feature in question, but rather is the result of targeted action.

### SUMMARY

According to the present disclosure, in a method for charging a high-voltage battery (for example a traction battery of an electric vehicle), the high-voltage battery having a battery nominal voltage (for example 800 V) is provided and a charging station having a charging nominal voltage (for example 400 V) that is smaller than the battery nominal voltage is provided. The high-voltage battery may be intended, without being restricted thereto, for example, to supply power to a high-voltage on-board power system of a vehicle, for example an electric drive of an electric vehicle, such as for example a hybrid electric vehicle (HEV) or battery electric vehicle (BEV).

The method furthermore includes electrically connecting a station-side protective earth terminal to a battery-side protective earth terminal in order to form a common protective earth (also referred to as “PE”) between them. With respect to the protective earth, the charging station symmetrically provides in each case half the charging nominal voltage between a first station-side high-voltage potential (for example positive HV potential) and the protective earth and half the charging nominal voltage between a second station-side high-voltage potential (for example negative HV potential) and the protective earth.

Furthermore, the method makes provision to equalize a voltage between a first battery-side high-voltage potential (for example positive HV battery potential) and the protective earth to half the charging nominal voltage by controlled dissipation of a leakage current between a first battery-side high-voltage potential and the protective earth. Moreover, the first station-side high-voltage potential is electrically connected to the first battery-side high-voltage potential, and the second station-side high-voltage potential is electrically connected to a second battery-side high-voltage potential (for example negative HV battery potential), wherein the voltage between the second station-side high-voltage potential and the protective earth is stepped up to a voltage between the second battery-side high-voltage potential and the protective earth (for example by way of a single DC/DC converter) in order to transfer electrical energy from the charging station to the high-voltage battery (also referred to herein as charging process).

During the charging process, the leakage current is controlled through resistance control of a leakage resistance that acts functionally between the first battery-side high-voltage potential and the protective earth. The resistance value of the leakage resistance is always determined by the electrical quantities current and voltage. The voltage between the battery-side HV potential and the protective earth is essentially a DC voltage, which may have a certain (residual) ripple. In other words, both a voltage value, for example the instantaneous voltage between the first battery-side HV potential and the protective earth, and a current value, for example the instantaneous value of the leakage current, are incorporated into the resistance control.

As a general rule, when charging a high-voltage battery at a charging station, it is necessary to ensure PE symmetry on the charging station side, that is to say the absolute value of the voltage between the first HV potential of the charging station and the protective earth corresponds essentially to the voltage between the second HV potential of the charging station and the protective earth. Usually, it is possible to observe a residual ripple of the voltage potential carried on the protective earth, which residual ripple makes reliable charging operation, in particular in this case compliance with the station-side PE symmetry, more difficult and significantly restricts a possible operating range of a charging circuit.

Through resistance control, that is to say of the leakage current controlled by the resistance control, the present disclosure surprisingly makes it possible to establish the station-side PE symmetry in a reliable, stable and precise manner during a charging process of the type described above (that is to say battery nominal voltage>charging nominal voltage) and to maintain it throughout the entire charging process.

In particular, the resistance control makes it possible to keep the PE symmetry constant regardless of an instantaneous voltage level of the high-voltage battery. It is possible to perform monitoring of an insulation resistance between the battery-side high-voltage potentials and the protective earth (for example by way of an ISO monitor) in a manner largely unaffected by the forced equalization of the respective battery-side high-voltage potentials to the station-side PE symmetry.

In contrast to the control of the leakage current according to the present disclosure by way of the resistance control as disclosed herein, constant current control requires for example the setpoint current required for the control to have to be adapted continuously to a present high-voltage situation (that is to say voltage between HV potential and PE). For this purpose, the current control circuit additionally has to be overlaid with a voltage control circuit that exhibits significantly slower dynamic behavior and that ensures that conventional insulation monitoring does not detect an excessively high current change that would be interpreted as defective insulation of the charging circuit, which would result in interruption of the charging process.

The present disclosure does not provide such an overlaid voltage control loop, and so the method according to the present disclosure is also easier to implement.

The present disclosure makes it possible, in a reliable manner, to carry out charging of high-voltage batteries, such as for example 800 V batteries, at charging stations with a lower charging nominal voltage, for example 400 V. Regardless of the amount by which the actual battery nominal voltage is greater than the charging nominal voltage, it is possible to extend technical compatibility to numerous further charging stations or to ensure technical compatibility therefor.

One advantageous embodiment of the present disclosure makes provision for a voltage (that is to say measured voltage) between the first battery-side high-voltage potential and the protective earth to be measured and for the leakage current (that is to say measured current) associated with this voltage to be measured and for a resistance setpoint value specification (that is to say setpoint resistance) for the resistance control of the leakage resistance to be calculated therefrom. The measured voltage and the measured current represent actual values of the respective physical quantities. The voltage measurement may be able to be activated and deactivated selectively without necessarily being limited to being able to be switched on and off. Preferably, the voltage measurement takes place in a high-resistance state, for example with an input resistance of at least 10 MΩ or a few multiples of 10 MΩ, for example 20 MΩ, 30 MΩ, 40 MΩ or 50 MΩ, including intermediate values. This ensures that the voltage measurement does not substantially negatively affect determination and monitoring of the insulation resistance and thus reliable performance of the charging process.

According to another advantageous development of the subject matter of the present disclosure, a setpoint resistance of the leakage resistance is calculated from the measured voltage and the measured leakage current following the subsiding of a transient settling process at the start of the energy transfer (that is to say of the charging process) after a substantially stable energy transfer state has been reached, and is kept constant in the subsequent control of the leakage current. According thereto, the setpoint resistance is calculated automatically based on the voltage and current measured values after the voltage situations have been adjusted and is then set within the permissible limits. During the settling process at the start of the energy transfer (that is to say shortly after the charging process is activated), the setpoint resistance may be changed dynamically, this preferably being limited downwards by a predetermined, constant minimum value that the setpoint resistance used for the resistance control is not permitted to fall below. The convergence behavior of the resistance control may thereby be further improved as a whole.

A further advantageous embodiment of the present disclosure makes provision for an insulation resistance between the first battery-side high-voltage potential and the protective earth and/or between the second battery-side high-voltage potential and the protective earth to be ascertained and monitored by way of an insulation monitoring device (for example ISO monitor), wherein the calculated leakage resistance is provided to the insulation monitoring device. The insulation monitoring device is thereby able to determine the total insulation resistance of the circuit directly from the transmitted leakage resistance and the determined insulation resistance. In other words, the instantaneous resistance value of the leakage resistance is taken into account by the insulation monitoring device in order to calculate the instantaneous total insulation resistance of the circuit. The total insulation resistance is able to be determined accurately, quickly and without any additional effort.

To further improve the resistance control, the measured voltage between the first battery-side high-voltage potential and the protective earth may be filtered by way of a low-pass filter before the leakage resistance is calculated in order to effectively suppress high-frequency interference in the measurement signal and further stabilize the resistance control.

Another advantageous development makes provision for the low-pass filter to be operated selectively with a first cutoff frequency and a second cutoff frequency, wherein the first cutoff frequency is greater than the second cutoff frequency and the low-pass filter is operated with the first cutoff frequency during a transient settling process at the start of the energy transfer or of the charging process and the low-pass filter is operated with the second cutoff frequency after a substantially stable energy transfer state has been reached. The takes account of the high dynamics at the start of the charging process and achieves fast and reliable convergence of the resistance control.

Optionally, the resistance control may include resistance drift compensation that automatically compensates for a creeping resistance change (that is to say one that occurs significantly slower compared to a duration of a single charging process) of an insulation resistance between the first battery-side high-voltage potential and the protective earth and/or between the second battery-side high-voltage potential and the protective earth when determining the leakage resistance. This should be understood to mean in particular a change in material properties of the insulation resistance due to ageing that may lead for example to undesirable creepage currents as insulation effect decreases, and reduce the effective insulation resistance. The resistance control for controlling the leakage current may thus be adapted automatically to the creeping resistance change of the insulation resistance even if a constant setpoint resistance is specified, and operating reliability is able to be further increased. The insulation resistance mentioned here may correspond to the insulation resistance determined by an insulation monitoring device, as already described above.

According to one particularly preferred embodiment, the leakage current is controlled by way of a transistor in a linear operating range (that is to say outside a saturated state). Transistor components, for example power semiconductors such as FETs or MOSFETs, which are able to switch and carry high currents, are generally readily available. The current dissipation may therefore be implemented at low cost. In addition, the transistor allows highly dynamic control of the leakage current, which reliably prevents any possible interruption of the charging process due to an insulation resistance that has been incorrectly ascertained as being too low, in particular during a transient switch-on process, for example immediately after the start of the charging process (that is to say energy transfer).

Since the transistor controls the leakage current only between the first battery-side high-voltage potential and the protective earth, the maximum voltage to be switched across the transistor is of the order of magnitude of only half the charging nominal voltage. Therefore, advantageously, transistors having a lower load capacity may be used to control the leakage current, for example 650 V transistors instead of, as is usual, 1200 V transistors in the case of charging processes to be carried out at 400 V charging stations.

In order to further increase operational safety, the transistor may be short-circuited by way of a clamping circuit in the event of an overvoltage between an input terminal receiving the leakage current (for example drain or source terminal) and an output terminal outputting the leakage current (that is to say source or drain terminal).

The resistance control may preferably be carried out by way of a digital processing unit, for example a microprocessor, microcontroller, etc. In this case, the resistance control itself may be implemented exclusively in software. This allows a high degree of flexibility and allows the various disclosed embodiments to be adapted easily to different applications.

According to a further aspect of the present disclosure, a device for charging a high-voltage battery, for example a traction battery of an electric vehicle, having a battery nominal voltage (for example 800 V) at a charging station having a charging nominal voltage (for example 400 V) that is smaller than the battery nominal voltage, has a battery-side protective earth terminal for connection to a station-side protective earth terminal in order to form a common protective earth between them when they are connected, with respect to which protective earth the charging station symmetrically provides in each case half the charging nominal voltage between a first station-side high-voltage potential (for example positive HV potential) and the protective earth and half the charging nominal voltage between a second station-side high-voltage potential (for example negative HV potential) and the protective earth.

The high-voltage battery may be intended, without necessarily being restricted thereto, for example, to supply power to a high-voltage on-board power system of a vehicle, for example an electric drive of an electric vehicle, such as for example a hybrid electric vehicle (HEV) or battery electric vehicle (BEV).

Moreover, according to the present disclosure, the device has a first battery-side charging terminal, connected to a first battery-side high-voltage potential (for example positive HV battery potential), for connection to the first station-side high-voltage potential and a second battery-side charging terminal, connected to a second battery-side high-voltage potential (for example negative HV battery potential), for connection to the second station-side high-voltage potential and a step-up converter (for example DC/DC converter) in order to convert a voltage between the second station-side high-voltage potential and the protective earth to a voltage between the second battery-side high-voltage potential and the protective earth.

Furthermore, the charging device has a controller that is configured to carry out a method according to one of the embodiments disclosed herein, in order to equalize a voltage between the first battery-side high-voltage potential and the protective earth to half the charging nominal voltage of the charging station by controlled dissipation of a leakage current through resistance control of a leakage resistance that acts functionally between the first battery-side high-voltage potential and the protective earth.

The controller may be designed for example as a digital processing unit, for example a microprocessor, microcontroller, digital signal processor (DSP), etc.

It should be noted that, with regard to device-related definitions of terms and the effects and advantages of device-related features, reference may be made in full to the disclosure of corresponding definitions, effects and advantages of the method according to the present disclosure, and vice versa. In this respect, any repetitions of explanations of correspondingly identical features or their effects and advantages are largely dispensed with in order to make the description more compact, without such omissions being interpreted as a restriction for the respective subject matter of the present disclosure.

According to one preferred embodiment of the subject matter of the present disclosure, provision is furthermore made for an insulation monitoring device for ascertaining and monitoring an insulation resistance between the first battery-side high-voltage potential and the protective earth and/or between the second battery-side high-voltage potential and the protective earth. The insulation monitoring device reliably ensures operational safety during a charging process by interrupting the charging process in the event of the insulation resistance value falling below a critical resistance value.

Another advantageous development makes provision for a transistor (for example power semiconductor such as FET, MOSFET, etc.) for controlling the leakage current that is able to be operated in a linear range (that is to say outside a saturated state).

Moreover, provision may be made for a clamping circuit that is designed, in the event of an overvoltage between an input terminal (for example drain terminal), receiving the leakage current, of the transistor and an output terminal (for example source terminal), outputting the leakage current, of the transistor, to short-circuit the input terminal and the output terminal in order to further increase the operational safety of the device.

In this sense, provision may also advantageously be made for a controllable switching element (for example relay) for selectively galvanically isolating the transistor from the first battery-side high-voltage potential and/or from the second battery-side high-voltage potential.

### BRIEF DESCRIPTION OF THE DRAWINGS

Further features and advantages of the various disclosed embodiments will become apparent from the following description of exemplary embodiments, which should not be understood to be restrictive, of the present disclosure, which will be explained in more detail below with reference to the drawing. In this drawing, in each case schematically:

FIG. 1 shows a functional diagram of one exemplary embodiment of a device for charging a high-voltage battery at a charging station according to one embodiment in a first operating state,

FIG. 2 shows the device from FIG. 1 in a second operating state,

FIG. 3 shows the device from FIG. 1 in a third operating state,

FIG. 4 shows the device from FIG. 1 in a fourth operating state,

FIG. 5 shows a detailed view of part of the device from FIG. 4,

FIG. 6 shows a functional diagram of one exemplary embodiment of a method for charging a high-voltage battery at a charging station according to an embodiment, and

FIG. 7 shows a functional diagram of a further exemplary embodiment of a method for charging a high-voltage battery at a charging station according to an embodiment.

In the various figures, parts that are equivalent in terms of their function are always provided with the same reference signs, and so they are generally also described only once.

### DETAILED DESCRIPTION

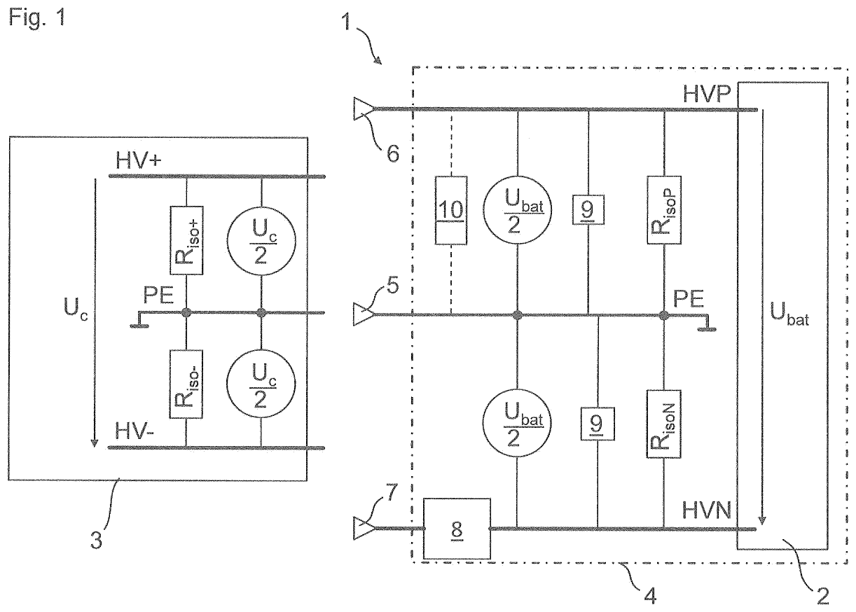

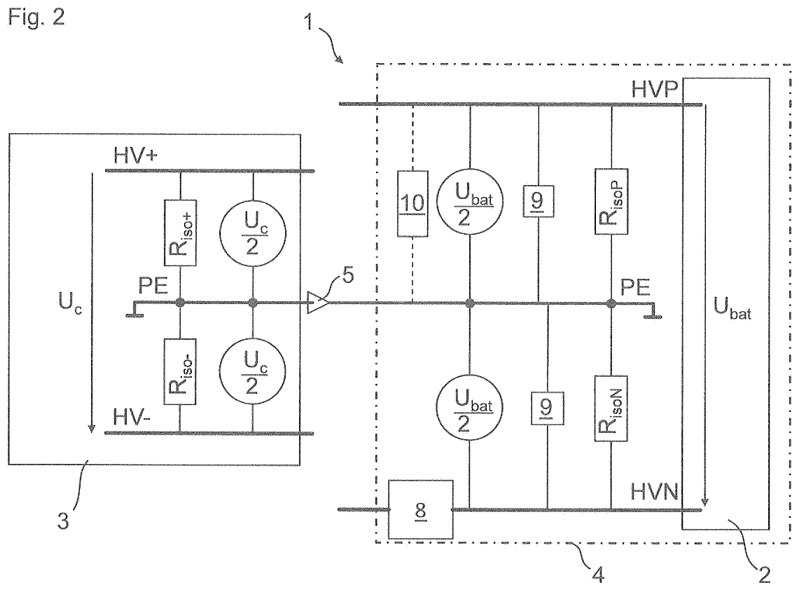

FIG. 1 illustrates a functional diagram of one exemplary embodiment of a device 1 for charging a high-voltage battery 2 at a charging station 3 according an embodiment in a first operating state. FIGS. 2, 3 and 4 illustrate the device 1 in a second, third and fourth operating state, respectively. They serve to illustrate one exemplary embodiment of a method for charging the high-voltage battery 2 at the charging station 3 according to an embodiment.

The device 1 shown in FIG. 1 is used here, by way of example and without necessarily being restricted thereto, in an electric vehicle 4 (for example HEV or BEV) in order to charge the HV battery 2, which here by way of example is a traction battery of the vehicle 4, at the charging station 3. The HV battery 2 has for example a battery nominal voltage of 800 V. A battery voltage provided between a first battery-side high-voltage potential HVP and a second battery-side high-voltage potential HVN is denoted U_{bat} in the figures. The charging station 3 has for example a maximum charging nominal voltage of 400 V. A charging voltage provided between a first station-side high-voltage potential HV+ and a second station-side high-voltage potential HV− is denoted U_{c} in the figures.

Furthermore, FIG. 1 shows a protective earth PE both on the station side and on the battery side. Both protective earth parts are able to be electrically connected to a battery-side protective earth terminal 5 via a station-side protective earth terminal (not illustrated explicitly) in order to form a common protective earth PE between them, as illustrated in FIG. 2.

With respect to the protective earth PE, the charging station 3 symmetrically provides in each case half U_{c}/2 the charging voltage U_{c} between a first station-side high-voltage potential HV+ and the protective earth PE and half U_{c}/2 the charging voltage U_{c} between a second station-side high-voltage potential HV− and the protective earth (PE).

Battery-side charging terminals 6 and 7 for electrically connecting the first battery-side HV potential HVP to the first station-side HV potential HV+ or for electrically connecting the second battery-side HV potential HVN to the second station-side HV potential HV− are likewise illustrated in FIG. 1.

The charging device 1 from FIG. 1 furthermore has a DC/DC step-up converter 8, which is connected in series between the second charging terminal 7 and the second battery-side HV potential HVN. The DC/DC step-up converter 8 is configured such that it raises the DC charging voltage U_{c} (in the present case 400 V) to the battery nominal voltage U_{bat} (in the present case 800 V), that is to say the DC/DC step-up converter 8 raises the voltage provided by the charging station 3 by 400 V in the present case, that is to say the step-up voltage U_{boost} is 400 V in the example illustrated in FIG. 1.

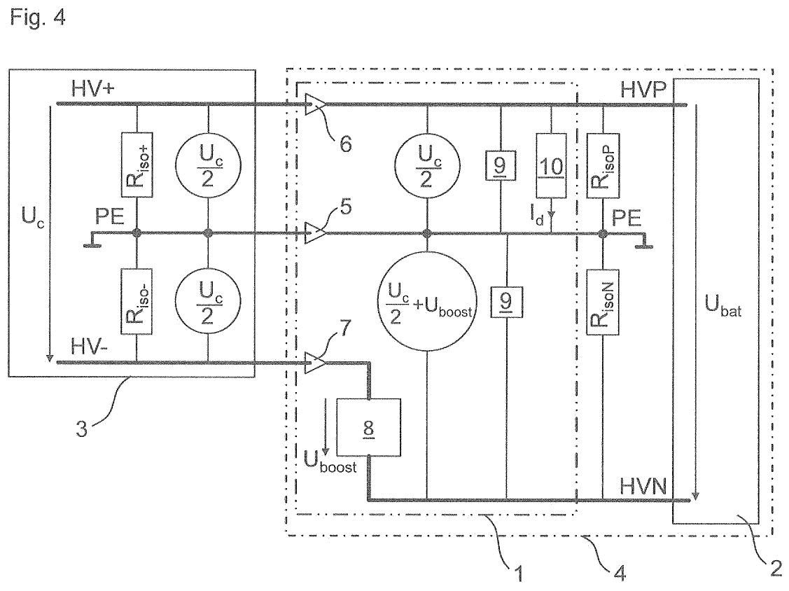

For safety reasons, insulation monitoring devices 9 or what are known as ISO monitors are usually used in high-voltage grids such as the grid temporarily formed by the charging station 3 and the HV battery 2 during a charging process to determine and monitor an insulation resistance R_{isoP}, R_{isoN} between PE and the corresponding battery-side HV potential HVP or HVN, as illustrated in FIG. 1. If the ascertained insulation resistances R_{isoP}, R_{isoN} fall below predefined resistance threshold values, a safety mechanism (not illustrated) is tripped in order to immediately interrupt an energy transfer (cf. FIG. 4) between the charging station 3 and the HV battery 2, for example by opening a switch, relay and the like. It goes without saying that the insulation monitoring devices 9 may be components of the charging device 1. However, the disclosed embodiments are not necessarily restricted thereto. The monitoring devices 9 may be components that are provided outside the charging device 1, that is to say not contained in the charging device 1 itself.

The respective insulation resistances R_{isoP}, R_{isoN} are monitored by the battery-side insulation monitoring devices 9. Although not illustrated in FIG. 1, it goes without saying that similar insulation monitoring devices may also be provided in the charging station 3.

In the situation illustrated in FIG. 1, one half of the battery voltage U_{bat} with respect to the protective earth PE is present between the HV potential HVP and PE (that is to say U_{bat}/2), and the other half is present between the HV potential HVN and PE (that is to say U_{bat}/2), as illustrated in FIG. 1.

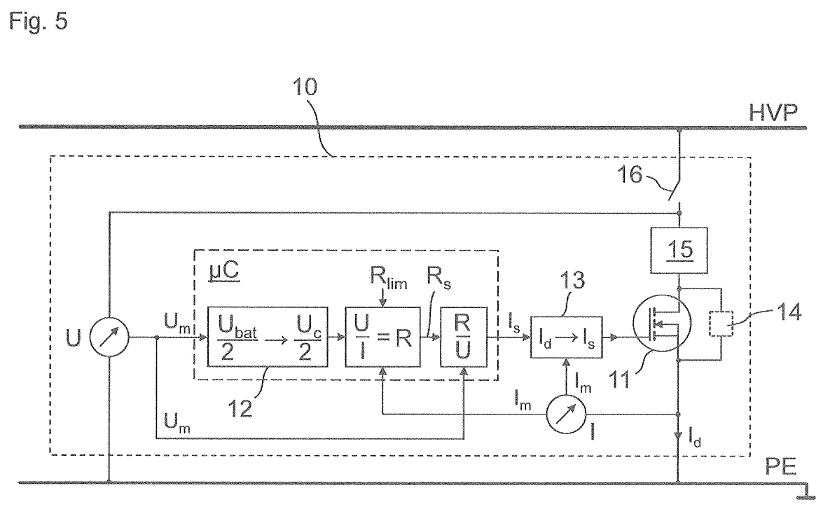

FIG. 1 furthermore shows a functional leakage resistance 10 of the exemplary charging device 1, which is illustrated in detail in FIG. 5 and will be explained in more detail in the description of FIG. 5.

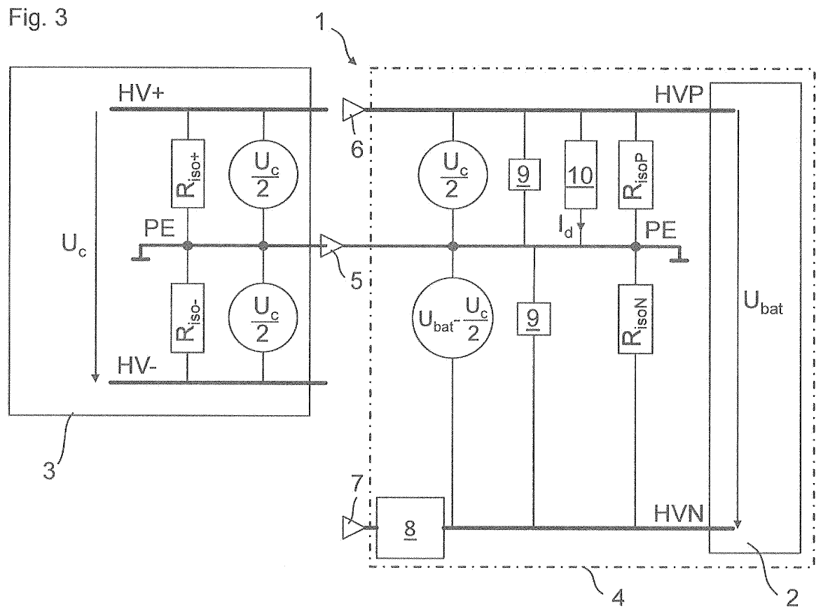

With reference to FIGS. 1 to 4, a description will now be given of one exemplary embodiment of a method according to an embodiment for charging a high-voltage battery (for example HV battery 2), including the following steps:
providing the high-voltage battery 2 having a battery nominal voltage U_{bat} (cf. FIG. 1),
providing a charging station (for example charging station 3) having a charging nominal voltage U_{c} that is smaller than the battery nominal voltage (cf. FIG. 1),
electrically connecting a station-side protective earth terminal to a battery-side protective earth terminal (for example terminal 5) in order to form a common protective earth PE between them, with respect to which protective earth the charging station 3 symmetrically provides in each case half U_{c}/2 the charging nominal voltage U_{c} between a first station-side high-voltage potential HV+ and the protective earth PE and half U_{c}/2 the charging nominal voltage U_{c} between a second station-side high-voltage potential HV− and the protective earth PE (cf. FIG. 2),
equalizing a voltage between a first battery-side high-voltage potential HVP and the protective earth PE to half the charging nominal voltage (U_{c}/2) by controlled dissipation of a leakage current I_{d} between a first battery-side high-voltage potential HVP and the protective earth PE (cf. FIG. 3),
electrically connecting the first station-side high-voltage potential HV+ to the first battery-side high-voltage potential HVP and electrically connecting the second station-side high-voltage potential HV− to a second battery-side high-voltage potential HVN, wherein the voltage between the second station-side high-voltage potential HV− and the protective earth PE is stepped up to a voltage between the second battery-side high-voltage potential HVN and the protective earth PE (for example by way of the DC/DC converter 8) in order to transfer electrical energy from the charging station 3 to the high-voltage battery 2 (cf. FIG. 4), and
controlling the leakage current I_{d} by way of resistance control of a leakage resistance 10 that acts functionally between the first battery-side high-voltage potential HVP and the protective earth PE.

It is apparent from FIGS. 1 to 4 that, without dissipation of the leakage current I_{d}, an asymmetry, that is to say a shift of the electrical potential between the high-voltage sides HV+ and HVP with respect to PE, leads to a situation whereby high transient currents would flow between the charging station 3 and the high-voltage battery 2 immediately after the electrical connection between them has been established (that is to say following activation of the charging process). This shift may lead to an insulation voltage between the HV potentials HVP, HVN, HV+, HV− and PE being exceeded. In addition, the insulation monitoring devices 9 would ascertain an incorrect insulation resistance R_{isoP} and/or R_{isoN} due to the high compensation currents. The high current rise would be interpreted as an erroneous insulation resistance R_{isoP}, R_{isoN} and the charging process would be interrupted.

The disclosed embodiment effectively avoids such operating states and enables reliable, safe and efficient charging of the high-voltage battery 2 at the charging station 3, which provides a charging voltage U_{c} that is smaller than the battery voltage U_{bat} of the high-voltage battery 2.

FIG. 5 illustrates a detailed view of the functional leakage resistance 10 of the device 1 from FIG. 4. As may be seen, in the present charging device 1 or charging method, the leakage current I_{d} is controlled by way of a transistor 11 (for example power semiconductor switch such as FET, MOSFET or the like), wherein the transistor 11 is operated in a linear operating range.

A controller μC, which is preferably designed as a digital processing unit such as for example a microprocessor, microcontroller, DSP or the like and carries out the method according to an embodiment, is used to drive the transistor 11 such that the current dissipation I_{d} behaves, in functional terms, essentially like a controlled ohmic resistance between the high-voltage potential HVP and PE with an adjustable resistance value. This controllable resistance is referred to herein as leakage resistance 10.

The leakage current I_{d} is controlled by way of resistance control of the leakage resistance 10 such that the voltage between the first battery-side high-voltage potential HVP and the protective earth PE is equalized to half the charging nominal voltage U_{c}/2 of the charging station 3. The resistance control is illustrated in FIG. 5 within the outlines of the controller μC with its essential functional groups.

As may be seen, in the present case, a voltage Uₘ (that is to say measured voltage) is measured between the first battery-side high-voltage potential HVP and the protective earth PE. In addition, the leakage current I_{d} associated with this measured voltage Uₘ is measured as a measured current Iₘ. A resistance setpoint value specification, that is to say a resistance setpoint value Rₛ, for the resistance control of the leakage resistance 10 is calculated from the measured values Uₘ and Iₘ. The measured voltage Uₘ and the measured current Iₘ represent actual values of the respective physical quantities.

As may be seen in FIG. 5, one component of the resistance control is voltage control 12, which regulates the voltage U_{bat}/2 (cf. FIG. 1) that is normally present between the HV potential HVP and PE to half the charging voltage U_{c}/2, which represents the voltage setpoint value for the voltage control 12, and may be designed for example as a PI controller. For this purpose, the measured voltage Uₘ is supplied to the voltage control 12, as illustrated in FIG. 5. The voltage value output by the voltage control 12 is then converted into a resistance value R, taking into account the measured current Iₘ, in order to obtain the resistance setpoint value specification Rₛ. To increase operational safety, the calculation of the setpoint resistance R may be limited downwards by a predeterminable resistance lower limit Rₗᵢₘ. In particular at the start of the charging process, which constitutes a transient process, the resistance limit Rₗᵢₘensures that the resistance control does not carry out regulation to impermissibly small resistance values R. The regulated resistance R thus has the minimum resistance Rₗᵢₘin any case.

Since the leakage current I_{d} is controlled by way of the transistor 11, the resistance control converts the setpoint resistance Rs, taking into account the recorded measured voltage Uₘ, into a setpoint current Iₛ, which is supplied to current control 13 or a current control loop, which may be designed for example as a PID controller, as illustrated in FIG. 5. The current control 13 controls the transistor 11 such that it channels the leakage current I_{d} corresponding to the previously determined setpoint resistance Rₛ at the measured voltage Uₘ that is present instantaneously across the transistor 11. The leakage resistance 10 thus behaves, in functional terms, like a real ohmic resistance that would be connected between the HV potential HVP and the protective earth PE.

The resistance control of the present charging device 1 is carried out completely by the digital processing unit μC, and is thus digital resistance control in this case. The current control 13 may optionally likewise be driven by the digital processing unit μC, although the current control 13 in the exemplary embodiment illustrated in FIG. 5 is illustrated outside the digital processing unit μC and, in this case, is implemented in analog form, for example using an operational amplifier (not illustrated). The current setpoint value specification Iₛ for the current control 13 may be provided in analog form by way of a digital-to-analog converter (DAC) or by way of a pulse width-modulated signal (PWM).

FIG. 5 furthermore shows that the exemplary charging device 1 may have an optional clamping circuit 14, using which the transistor 11 is short-circuited in the event of an overvoltage between an input terminal receiving the leakage current I_{d} and an output terminal outputting the leakage current I_{d}.

FIG. 5 furthermore illustrates a resistor network 15, which, by way of example, may have a resistance of around 100 kΩ in a 3P3S configuration (not illustrated in more detail) of individual resistors (in this case, for example, 3 parallel-connected resistor strings each containing 3 series resistors). The resistor network 15 limits the maximum leakage current I_{d} in order to further increase the operational safety of the device 1.

Furthermore, FIG. 5 shows a controllable switching element 16 (for example relay) for selectively galvanically isolating the transistor 11 from the first battery-side high-voltage potential HVP.

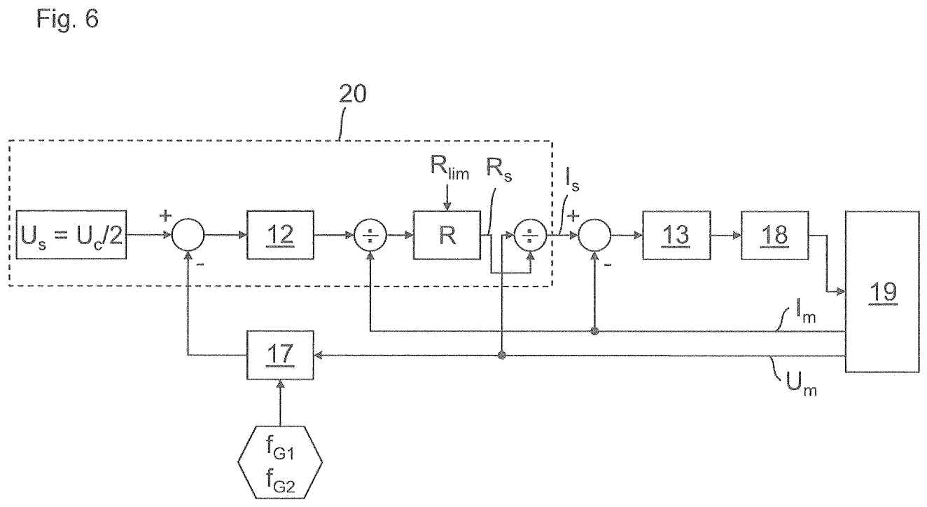

FIG. 6 illustrates a functional diagram of a further exemplary embodiment of a method for charging a high-voltage battery (for example HV battery 2) at a charging station (for example charging station 3) according to an embodiment. In addition to the functional components already shown in FIG. 5, FIG. 6 additionally shows a low-pass filter 17. In this case, the measured voltage Uₘ between the first battery-side high-voltage potential HVP and the protective earth PE is filtered by way of the low-pass filter before the setpoint resistance Rₛ is calculated. In addition, the essential part of the resistance control in FIG. 6 is identified by a dashed border 20.

In the present exemplary embodiment, the low-pass filter 17 may be operated selectively with a first cutoff frequency f_{G1} and a second cutoff frequency f_{G2}, wherein the first cutoff frequency f_{G1} is greater than the second cutoff frequency f_{G2}. The low-pass filter 17 is in this case operated with the first cutoff frequency f_{G1} during a transient settling process at the start of the energy transfer (that is to say at the start of the charging process) and then operated with the second cutoff frequency f_{G2} after a substantially stable energy transfer state has been reached. In spite of the high electrical dynamics during the transient settling process, this achieves fast and reliable convergence of the resistance control.

The system to be controlled, for example the charging of the HV battery 2 at the charging station 3 using the control of the leakage current I_{d} by way of the transistor 11, is illustrated at 18 in FIG. 6, and a measuring device for recording the measured quantities Uₘ and Iₘ is illustrated at 19. In addition to the voltage and current measured values Uₘ and Iₘ, respectively, the measuring device 19 is able to record further measured values such as for example a temperature (not illustrated) of the charging circuit or of the leakage resistance 10, of the HV battery 2 and the like, which may likewise be taken into account for the operation of the charging device, in order for example to interrupt the charging process if permissible limit values are exceeded.

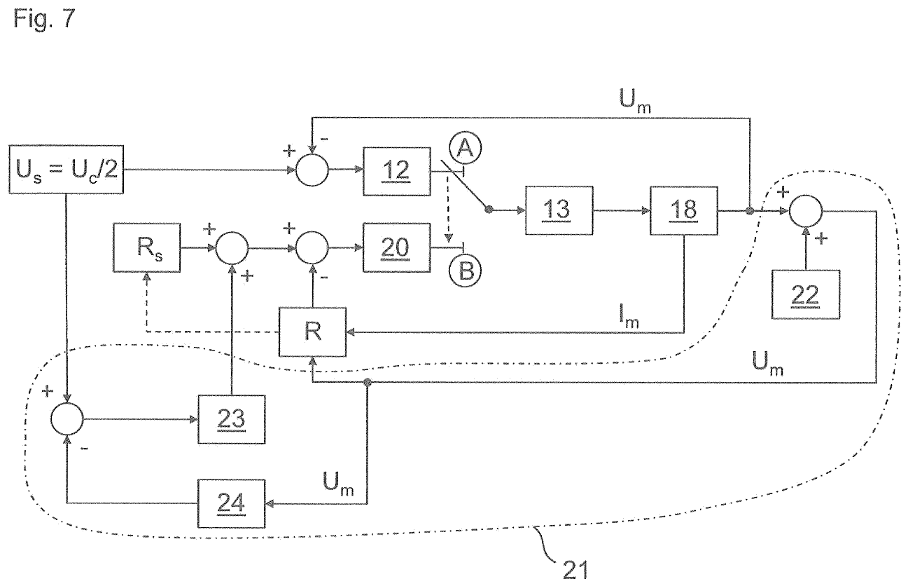

FIG. 7 illustrates a functional diagram of yet another exemplary embodiment of a method for charging a high-voltage battery (for example HV battery 2) at a charging station (for example charging station 3) according to an embodiment. In the method illustrated here, the resistance control additionally includes resistance drift compensation 21, illustrated with a dot-and-dash border, which automatically compensates for a creeping resistance change 22, and thus one that occurs significantly slower compared to a duration of a single charging process, of an insulation resistance between the first battery-side high-voltage potential HVP and the protective earth PE (for example insulation resistance R_{isoP}) and/or between the second battery-side high-voltage potential HVP and the protective earth PE (for example insulation resistance R_{isoN}) when determining the setpoint resistance Rₛ of the leakage resistance (for example leakage resistance 10). The resistance change 21 represents a disturbance in the resistance control of the leakage resistance 10 (cf. FIG. 1). This is taken into account by a resistance drift controller 23 when determining the setpoint resistance Rₛ. In addition, the measured voltage Uₘ is filtered in this case by way of a filter 24 before the drift control 23.

FIG. 7 does not illustrate the measuring device 19, but rather only the measured quantities Uₘ and Iₘ taken from the controlled system 18.

In addition, the method illustrated in FIG. 7 has the particular feature, compared to the method illustrated in FIG. 6, that, at the start of the charging process, that is to say during the transient settling process when implementing the energy transfer between the charging station 3 and the HV battery 2, of using only voltage control, for example the voltage control 12, to determine the setpoint current Iₛ for the current control 13 of the leakage current I_{d} in a first control stage A. After the settling process has subsided, that is to say the energy transfer has reached a substantially stable state and therefore the voltage present between the HV potential HVP and the protective earth PE has settled to half the charging voltage U_{c}/2, the method illustrated in FIG. 7 changes to the second control stage B (indicated by dashed lines) in order to carry out the resistance control of the leakage resistance 10 (cf. FIG. 1) during the charging process. The first control stage A is ended by the change.

Upon the change from stage A to B, in the exemplary embodiment illustrated here, the setpoint resistance Rₛ of the leakage resistance 10 is calculated from the measured voltage Uₘ and the measured leakage current Iₘ after the subsiding of a transient settling process and is kept constant in the subsequent control of the leakage current I_{d}, that is to say in the resistance control. The resistance setpoint value Rₛ is therefore in this case not changed further during the charging process.

It should be mentioned that, preferably, in the exemplary embodiments described above, the insulation resistance R_{isoP}, R_{isoN} between the first battery-side high-voltage potential HVP and the protective earth PE and/or between the second battery-side high-voltage potential HVP and the protective earth PE may be ascertained and monitored by way of an insulation monitoring device (for example the insulation monitoring device 9), wherein the calculated leakage resistance R is provided to the insulation monitoring device (not explicitly illustrated in the figures) in order to determine a total insulation resistance of the charging circuit comprising the insulation resistance R_{isoP}, R_{isoN} and the leakage resistance R.

The method according to the present disclosure for charging a high-voltage battery as disclosed herein and the charging device according to an embodiment are not each limited to the specific embodiments described herein, but rather also encompass further embodiments with the same effect and that result from technically feasible further combinations of the features of all of the subjects of the disclosed embodiments as described herein. In particular, the features and combinations of features mentioned above in the general description and the description of the figures and/or shown just in the figures may be used not only in the respective combinations explicitly mentioned herein, but also in other combinations or on their own, without departing from the scope of the present disclosure.

In one particularly preferred embodiment, the charging device according to an embodiment is used to charge a high-voltage battery of an electric vehicle (for example traction battery having 800 V battery nominal voltage or higher) at a charging station that provides a lower charging voltage (for example max. 400 V) than the battery nominal voltage of the HV battery to be charged.

What is claimed is:

1. A method for charging a high-voltage battery, comprising the following steps:
providing the high-voltage battery having a battery nominal voltage;
providing a charging station having a charging nominal voltage that is smaller than the battery nominal voltage;
electrically connecting a station-side protective earth terminal to a battery-side protective earth terminal in order to form a common protective earth between them, with respect to the common protective earth, the charging station symmetrically provides in each case half the charging nominal voltage between a first station-side high-voltage potential and the protective earth and half the charging nominal voltage between a second station-side high-voltage potential and the protective earth;
equalizing a voltage between a first battery-side high-voltage potential and the protective earth to half the charging nominal voltage by controlled dissipation of a leakage current between the first battery-side high-voltage potential and the protective earth;
electrically connecting the first station-side high-voltage potential to the first battery-side high-voltage potential;
electrically connecting the second station-side high-voltage potential to a second battery-side high-voltage potential, wherein the voltage between the second station-side high-voltage potential and the protective earth is stepped up to a voltage between the second battery-side high-voltage potential and the protective earth in order to transfer electrical energy from the charging station to the high-voltage battery; and
controlling the leakage current by way of a resistance control of a leakage resistance that acts functionally between the first battery-side high-voltage potential and the protective earth.

2. The method as claimed in claim 1, further comprising:
measuring a measured voltage between the first battery-side high-voltage potential and the protective earth;
measuring the leakage current associated with the measured voltage; and
calculating a setpoint resistance for the resistance control of the leakage resistance from the measured voltage and the measured leakage current.

3. The method as claimed in claim 2, further comprising:
calculating the setpoint resistance of the leakage resistance from the measured voltage and the measured leakage current following a subsiding of a transient settling process at a start of the charging energy transfer after a substantially stable energy transfer state has been reached, and is kept constant in a subsequent control of the leakage current.

4. The method according to claim 3, further comprising:
ascertaining and monitoring an insulation resistance between the first battery-side high-voltage potential and the protective earth and/or between the second battery-side high-voltage potential and the protective earth by an insulation monitoring device, wherein the calculated leakage resistance is provided to the insulation monitoring device in order to determine a total insulation resistance comprising the insulation resistance and a leakage resistance.

5. The method as claimed in claim 2, further comprising:
filtering the measured voltage between the first battery-side high-voltage potential and the protective earth wherein the filtering is by way of a low-pass filter before the setpoint resistance is calculated.

6. The method as claimed in claim 5,
characterized in that
the low-pass filter is operated selectively with a first cutoff frequency and a second cutoff frequency, wherein the first cutoff frequency is greater than the second cutoff frequency and the low-pass filter is operated with the first cutoff frequency during a transient settling process at the start of the charging energy transfer and the low-pass filter is operated with the second cutoff frequency after a substantially stable energy transfer state has been reached.

7. The method as claimed in claim 1,
characterized in that
the resistance control comprises a resistance drift compensation that automatically compensates for a creeping resistance change of an insulation resistance between the first battery-side high-voltage potential and the protective earth and/or between the second battery-side high-voltage potential and the protective earth.

8. The method as claimed in claim 1,
characterized in that
the leakage current is controlled by way of a transistor in a linear operating range.

9. The method as claimed in claim 8,
characterized in that
the transistor is short-circuited by way of a clamping circuit in an event of an overvoltage between an input terminal receiving the leakage current and an output terminal outputting the leakage current.

10. The method as claimed in claim 1,
characterized in that
the resistance control is carried out by way of a digital processing unit.

11. A device to charge a high-voltage battery, having a battery nominal voltage, at a charging station. having a charging nominal voltage that is smaller than the battery nominal voltage, comprising:
a battery-side protective earth terminal for connection to a station-side protective earth terminal in order to form a common protective earth between them when they are connected, with respect to which protective earth the charging station symmetrically provides in each case half the charging nominal voltage between a first station-side high-voltage potential and the protective earth and half the charging nominal voltage between a second station-side high-voltage potential and the protective earth;
a first battery-side charging terminal, connected to a first battery-side high-voltage potential, for connection to the first station-side high-voltage potential;
a second battery-side charging terminal, connected to a second battery-side high-voltage potential, for connection to the second station-side high-voltage potential;
a step-up converter in order to convert a voltage between the second station-side high-voltage potential and the protective earth to a voltage between the second battery-side high-voltage potential and the protective earth; and
a controller that is configured to carry out a method in order to equalize a voltage between the first battery-side high-voltage potential and the protective earth to half the charging nominal voltage of the charging station by controlled dissipation of a leakage current through resistance control of a leakage resistance that acts functionally between the first battery-side high-voltage potential and the protective earth.

12. The device as claimed in claim 11,
characterized by
an insulation monitoring device adapted to ascertain and monitor an insulation resistance between the first battery-side high-voltage potential and the protective earth and/or between the second battery-side high-voltage potential and the protective earth.

13. The device as claimed in claim 11,
characterized by
a transistor configured to control the leakage current that is adapted to operate in a linear range.

14. The device as claimed in claim 13,
characterized by
a clamping circuit that is configured to, in an event of an overvoltage between an input terminal, receive the leakage current, of the transistor and an output terminal, output the leakage current, of the transistor, to short-circuit the input terminal and the output terminal.

15. The device as claimed in claim 13,
characterized by
a controllable switching element configured to selectively galvanically isolate the transistor from the first battery-side high-voltage potential and/or from the second battery-side high-voltage potential.

16. The device as claimed in claim 11, wherein the controller is configured to:
provide the high-voltage battery having a battery nominal voltage;
provide a charging station having a charging nominal voltage that is smaller than the battery nominal voltage;
electrically connect a station-side protective earth terminal to a battery-side protective earth terminal in order to form a common protective earth between them, with respect to the common protective earth, the charging station symmetrically provides in each case half the charging nominal voltage between a first station-side high-voltage potential and the protective earth and half the charging nominal voltage between a second station-side high-voltage potential and the protective earth;
equalize a voltage between a first battery-side high-voltage potential and the protective earth to half the charging nominal voltage by controlled dissipation of a leakage current between the first battery-side high-voltage potential and the protective earth;
electrically connect the first station-side high-voltage potential to the first battery-side high-voltage potential;
electrically connect the second station-side high-voltage potential to a second battery-side high-voltage potential, wherein the voltage between the second station-side high-voltage potential and the protective earth is stepped up to a voltage between the second battery-side high-voltage potential and the protective earth in order to transfer electrical energy from the charging station to the high-voltage battery; and
control the leakage current by way of a resistance control of a leakage resistance that acts functionally between the first battery-side high-voltage potential and the protective earth.
